(19) United States
(12) Patent Application Publication
(10) Pub. No.: US 2022/0102919 A1
(43) Pub. Date: Mar. 31, 2022

(54) ELECTRICAL CONNECTOR ASSEMBLY

(71) Applicant: 3M INNOVATIVE PROPERTIES COMPANY, St. Paul, MN (US)

(72) Inventor: Dennis L. Doye, Cedar Park, TX (US)

(21) Appl. No.: 17/310,605

(22) PCT Filed: Mar. 4, 2020
(86) PCT No.: PCT/IB2020/051886

§ 371 Date: Aug. 13, 2021

Related U.S. Application Data
(60) Provisional application No. 62/818,226, filed on Mar. 14, 2019.

(51) Int. Cl. H01R 13/66; H01R 12/62; G02B 6/42; H05K 1/11; H05K 7/20; H01R 13/502; H01R 24/60

(52) U.S. Cl. CPC H01R 13/6658; H01R 12/62; G02B 6/4261; H05K 1/117; H05K 2201/10356; H01R 13/502; H01R 24/60; H05K 2201/09445; H05K 7/2039

(57) ABSTRACT

An electrical connector assembly includes a housing and a circuit board. The housing includes opposing top and bottom walls and opposing first and second sidewalls connecting the top and bottom walls. The circuit board is at least partially disposed in the housing. The circuit board includes an upper surface and an opposing lower surface. The circuit board further includes a plurality of conductive rear pads disposed on the upper and lower surfaces. A separation between the rear pads disposed on the upper surface and the top wall of the housing is greater than a separation between the rear pads disposed on the lower surface and the bottom wall of the housing. Opposing first and second sidewall extensions extend upwardly from the opposing respective first and second sidewalls of the housing and define an open top channel therebetween that extends uninterrupted between the opposing first and second sidewall extensions.

### TECHNICAL FIELD

The present disclosure relates generally to an electrical connector assembly, and in particular, to an electrical connector assembly having multiple cables.

### BACKGROUND

Electrical connectors are often used to mate cables with input or output ports. Electrical connectors may have to conform to certain industry standards for connection with specific types of input or output ports.

### SUMMARY

In one aspect, the present disclosure provides an electrical connector assembly. The electrical connector assembly includes a housing and a circuit board. The housing includes opposing top and bottom walls, and opposing first and second sidewalls connecting the top and bottom walls. The top and bottom walls and the opposing first and second sidewalls define a housing cavity therebetween. The circuit board is at least partially disposed in the housing cavity. The circuit board includes an upper surface and an opposing lower surface. The circuit board further includes a front end and a cable end opposite the front end and disposed inside the housing cavity. The circuit board further includes a plurality of conductive front pads disposed on the upper and lower surfaces near the front end. The circuit board further includes a plurality of conductive rear pads disposed on the upper and lower surfaces between the front pads and the cable end and electrically connected to the front pads. A separation between the rear pads disposed on the upper surface and the top wall of the housing is S1. Further, a separation between the rear pads disposed on the lower surface and the bottom wall of the housing is S2. S1 is more than or equal to 1.5 times S2 (S1≥1.5 S2). The electrical connector assembly further includes stacked first, second and third flat cables terminated at the conductive rear pads and disposed on the top surface of the circuit board. The electrical connector assembly further includes a fourth flat cable terminated at the conductive rear pads disposed on the lower surface of the circuit board. The electrical connector assembly further includes opposing first and second sidewall extensions extending upwardly from the opposing respective first and second sidewalls of the housing and defining an open top channel therebetween that extends uninterrupted between the opposing first and second sidewall extensions.

### BRIEF DESCRIPTION OF THE DRAWINGS

Exemplary embodiments disclosed herein may be more completely understood in consideration of the following detailed description in connection with the following figures. The figures are not necessarily drawn to scale. Like numbers used in the figures refer to like components. However, it will be understood that the use of a number to refer to a component in a given figure is not intended to limit the component in another figure labeled with the same number.

FIG. 1 is a perspective view of an electrical connector assembly according to one embodiment of the present disclosure;

FIG. 2 is another perspective view of the electrical connector assembly of FIG. 1;

FIG. 3 is a partially-exploded view of the electrical connector assembly of FIG. 1;

FIG. 4 is a sectional perspective view of the electrical connector assembly of FIG. 1;

FIG. 5 is an exploded view of a housing of the electrical connector assembly according to one embodiment of the present disclosure;

FIG. 6 is another exploded view of the housing of FIG. 5;

FIG. 7 is a top perspective view of a circuit board of the electrical connector assembly according to one embodiment of the present disclosure;

FIG. 8 is a bottom perspective view of the circuit board of FIG. 7;

FIG. 9 is a detailed partially-exploded view of the electrical connector assembly according to one embodiment of the present disclosure;

FIG. 10 is a sectional perspective view of the housing with a circuit board according to one embodiment of the present disclosure;

FIG. 11 is another sectional perspective view of the housing with the circuit board according to one embodiment of the present disclosure;

FIG. 12 is a top perspective view of the circuit board connected to flat cables according to one embodiment of the present disclosure;

FIG. 13 is a bottom perspective view of the circuit board of FIG. 12; and

FIG. 14 is a sectional perspective view of the electrical connector assembly according to one embodiment of the present disclosure.

### DETAILED DESCRIPTION

In the following description, reference is made to the accompanying figures that form a part thereof and in which various embodiments are shown by way of illustration. It is to be understood that other embodiments are contemplated and may be made without departing from the scope or spirit of the present disclosure. The following detailed description, therefore, is not to be taken in a limiting sense.

Electrical connectors that are used for mating cables with input or output ports typically need to conform to certain industry standards. Electrical connectors may have to comply with a form factor required by the industry standard. An example of such a form factor is the Octal Small Format Pluggable (OSFP) form factor defined by an industry standard created by a committee known as an MSA (Multi-Source Agreement). Electrical connectors may also need to ensure adequate transfer of heat generated by one or more components. Further, cables with larger gauges or diameters may be required for certain applications, such as high speed applications. However, conventional electrical connectors may be unable to accommodate cables with larger gauges within the stipulated form factor while ensuring adequate heat transfer.

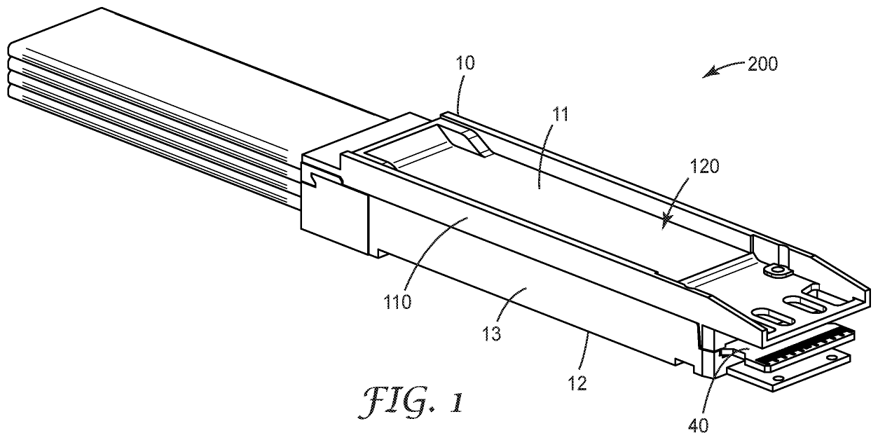

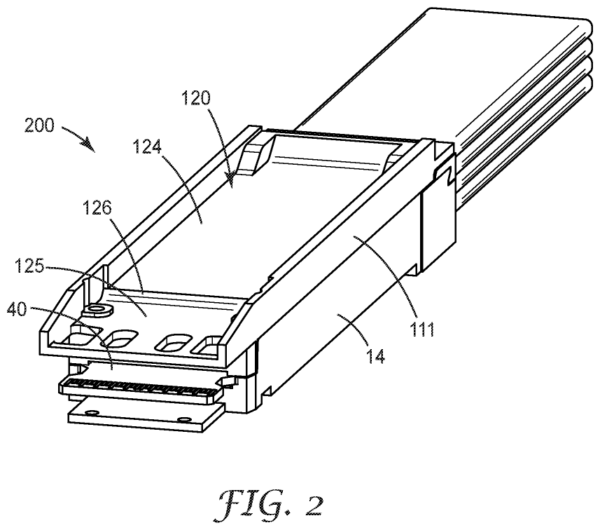

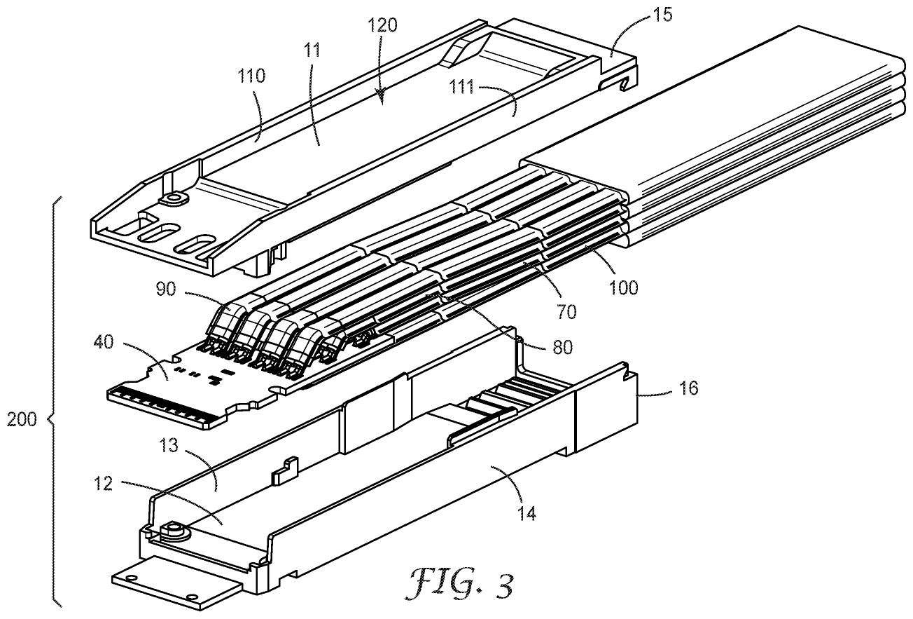

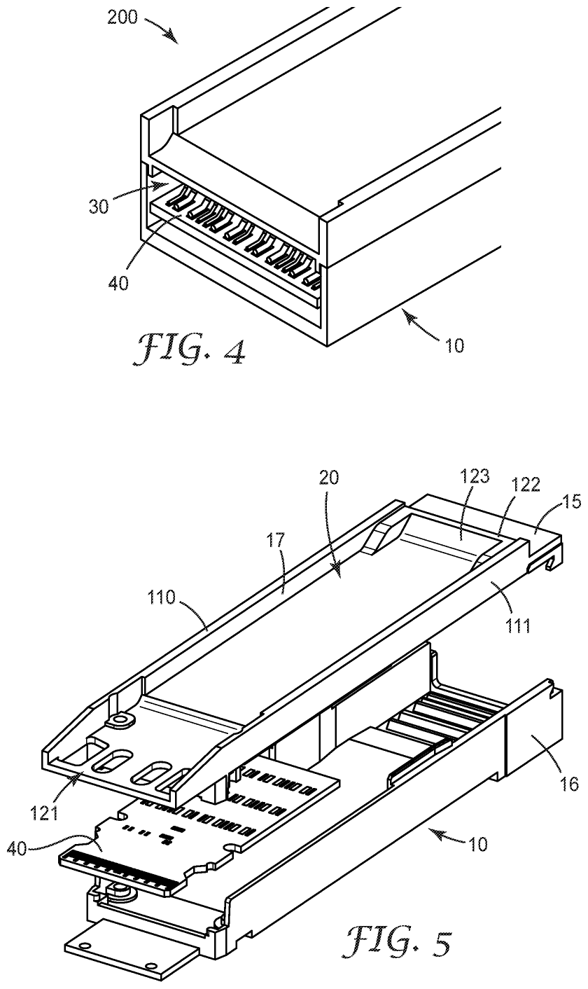

An electrical connector assembly of the present disclosure may accommodate cables with large gauges within an industry standard form factor (e.g., OSFP form factor) while ensuring adequate transfer of heat generated by the electrical connector assembly. The electrical connector assembly includes an open top channel that extends uninterrupted between opposing sidewall extensions. Air flowing through the open top channel may result in heat transfer. The open top channel may allow sufficient volume of air flow within a lesser height as compared to channels with multiple interruptions, such as fins. Decreasing the height of the open top channel may lead to greater space within the electrical connector assembly for receiving cables with larger gauges while ensuring that the overall height of the electrical connector assembly is within the industry standard form factor. Referring now to the Figures, FIGS. 1 to 4 illustrate an electrical connector assembly 200 including a housing 10 and a circuit board 40. The housing 10 includes a top wall 11, a bottom wall 12 opposing the top wall 11, a first sidewall 13, and a second sidewall 14 opposing the first sidewall 13. The opposing first and second sidewalls 13, 14 connect the top and bottom walls 11, 12. The opposing top and bottom walls 11, 12 and the opposing first and second side walls 13, 14 define a housing cavity 30 (shown in FIG. 4) therebetween. The circuit board 40 is at least partially disposed in the housing cavity 30. A shape and volume of the housing cavity 30 may be varied as per applications requirements. Further, the housing 10 may be made of any suitable material, such as a metal, an alloy, a composite, a plastic, and so forth.

In some embodiments, each of the top wall 11, the bottom wall 12, the first sidewall 13 and the second side wall 14 has a substantially planar configuration. In some other embodiments, one or more of the top wall 11, the bottom wall 12, the first sidewall 13 and the second side wall 14 may have a curved configuration. In some embodiments, the top and bottom walls 11, 12 are substantially parallel to each other. In some embodiments, an angle between the top and bottom walls 11, 12 may be less than about 3 degrees, less than about 5 degrees, or less than about 10 degrees. In some embodiments, the first and second sidewalls 13, 14 are substantially parallel to each other. In some embodiments, an angle between the first and second sidewalls 13, 14 may be less than about 3 degrees, less than about 5 degrees, or less than about 10 degrees. In some embodiments, an angle between the top wall 11 and each of the first and second sidewalls 13, 14 may be about 90 degrees. In some embodiments, the angle between the top wall 11 and each of the first and second sidewalls 13, 14 may be in a range from about 87 degrees to about 93 degrees, about 85 degrees to about 95 degrees, or about 80 degrees to about 100 degrees. In some embodiments, an angle between the bottom wall 12 and each of the first and second sidewalls 13, 14 may be about 90 degrees. In some embodiments, the angle between the bottom wall 12 and each of the first and second sidewalls 13, 14 may be in a range from about 87 degrees to about 93 degrees, about 85 degrees to about 95 degrees, or about 80 degrees to about 100 degrees.

The housing 10 further includes a first side wall extension 110 and a second sidewall extension 111 opposing the first side wall extension 110. The opposing first and second sidewall extensions 110, 111 extend upwardly from the opposing respective first and second sidewalls 13, 14 of the housing 10. In other words, the first sidewall extension 110 extends upwardly from the first sidewall 13 of the housing 10, while the second sidewall extension 111 extends upwardly from the second sidewall 14 of the housing 10. In some embodiments, an angle between the first sidewall extension 110 and the first sidewall 13 may be about 0 degrees. In some embodiments, the angle between the first sidewall extension 110 and the first sidewall 13 may be less than about 3 degrees, less than about 5 degrees, or less than about 10 degrees. In some embodiments, an angle between the second sidewall extension 111 and the second sidewall 14 may be about 0 degrees. In some embodiments, the angle between the second sidewall extension 111 and the second sidewall 14 may be less than about 3 degrees, less than about 5 degrees, or less than about 10 degrees. In some embodiments, the first and second sidewall extensions 110, 111 are substantially parallel to each other. In some embodiments, an angle between the first and second sidewall extensions 110, 111 may be less than about 3 degrees, less than about 5 degrees, or less than about 10 degrees. In some embodiments, each of the first and second sidewall extensions 110, 111 has a substantially planar configuration. In some other embodiments, one or more of the first and second sidewall extensions 110, 111 may have a curved configuration.

The opposing first and second sidewall extensions 110, 111 define an open top channel 120 (hereinafter referred to as “the channel 120”) therebetween that extends uninterrupted between the opposing first and second sidewall extensions 110, 111. In other words, the channel 120 is substantially devoid of any discontinuity or interruption between the first and second sidewall extensions 110, 111. For example, the channel 120 may not include any fins or grooves between the first and second sidewall extensions 110, 111. In the illustrated embodiment, the channel 120 includes a substantially flat first bottom surface 124 and a substantially flat second bottom surface 125. In other words, each of the first and second bottom surfaces 124, 125 is substantially planar. In some other embodiments, the channel 120 may include a smooth curved portion. In some embodiments, the first and/or second bottom surfaces 124, 125 may be defined by a top surface of the top wall 11. Further, the first and second bottom surfaces 124, 125 are disposed between inner surfaces of the first and second sidewall extensions 110, 111. In some embodiments, the inner surface of each of the first and second sidewall extensions 110, 111 is substantially planar. In some other embodiments, the inner surface of one or more of the first and second sidewall extensions 110, 111 may be curved. In some embodiments, the channel 120 may have a substantially U-shaped cross-section.

In some embodiments, an angle between the first and second bottom surfaces 124, 125 may be about 0 degrees, e.g., the first and second bottom surfaces 124, 125 are substantially parallel to each other. In some embodiments, the angle between the first and second bottom surfaces 124, 125 may be less than about 3 degrees, less than about 5 degrees, or less than about 10 degrees. Further, the first and second bottom surfaces 124, 125 are connected via one or more steps 126. Alternatively, the first and second bottom surfaces 124, 125 may be connected by a smooth inclined region. Each of the steps 126 extend between the first and second sidewall extensions 110, 111. Further, each of the steps 126 may be substantially L-shaped. A number and a height of each step 126 may be varied as per application requirements. Each of the steps 126 may be substantially smooth without any projections or grooves.

In some embodiments, the channel 120 is configured to transfer heat generated by the electrical connector assembly 200. Further, a shape and a volume of the channel 120 may be varied as per application requirements, for example, heat dissipation requirements of the electrical connector assembly 200. The channel 120 may enable air flow to facilitate transfer of heat generated by the electrical connector assembly 200.

The circuit board 40 is at least partially received within the housing cavity 30 of the housing 10. In some embodiments, the circuit board 40 may be secured within the housing cavity 30 by one or more projections extending from one or more walls of the housing 10, for example, the top wall 11 and the bottom wall 12. In some embodiments, the circuit board 40 may be detachably connected to the housing 10 by various methods, such as snap-fit connection, fasteners, and so forth.

Referring to FIG. 3, a first flat cable 70, a second flat cable 80 and a third flat cable 90 are stacked on top of each other and terminated at the circuit board 40. A fourth flat cable 100 is also terminated at the circuit board 40. The flat cables 70, 80, 90, 100 are at least partially received within the housing cavity 30. The housing 10 defines a first longitudinal end and a second longitudinal end opposite to the first longitudinal end. The circuit board 40 extends from the housing cavity 30 (shown in FIG. 4) near the first longitudinal end of the housing 10. Further, the flat cables 70, 80, 90, 100 extend from the housing cavity 30 at the second longitudinal end of the housing 10.

In some embodiments, each of the flat cables 70, 80, 90, 100 is a shielded flat electric cable having one or more conductor sets and one or more shielding films at least partially enclosing the one or more conductor sets. Each conductor set may include one or more insulated conductors. A number of conductor sets for each flat cable 70, 80, 90, 100 may be varied as per application requirements. A number of insulated conductors per conductor set may also be varied as per application requirements. For example, each conductor set may have a twinaxial configuration or a coaxial configuration. Further, the number of insulated conductors may be varied across the conductor sets of a given flat cable. In some embodiments, the flat cables 70, 80, 90, 100 may have a similar configuration. In some other embodiments, the flat cables 70, 80, 90, 100 may have different configurations.

The housing 10 may have an integral construction or a multi-part construction. Referring to FIGS. 3, 5 and 6, in some embodiments, the housing 10 includes an upper half 15 removably assembled to a lower half 16. The upper and lower halves 15, 16 define the housing cavity 30 therebetween. The circuit board 40 is received at least partially within the housing cavity 30. The upper and lower halves 15, 16 may be removably assembled to each other by various methods, for example, a snap-fit connection, one or more fasteners, or a combination thereof. The removable connection between the upper half 15 and the lower half 16 may facilitate assembly of the electrical connector assembly 200. For example, the circuit board 40 connected to the flat cables 70, 80, 90, 100 may be inserted between the upper and lower halves 15, 16 in a disassembled state of the upper and lower halves 15, 16. The upper and lower halves 15, 16 may be then assembled to each other. Further, the upper and lower halves 15, 16 may be detached from each other to allow servicing and/or replacement of one or more components of the electrical connector assembly 200. Upon assembly, the upper and lower halves 15, 16 define the housing cavity 30 therebetween.

The upper and lower halves 15, 16 may define a first opening therebetween near the first longitudinal end of the housing 10. The circuit board 40 may extend through the first opening. Further, the upper and lower halves 15, 16 may define a second opening therebetween at the second longitudinal end of the housing 10. The flat cables 70, 80, 90, 100 may extend through the second opening.

Referring to FIGS. 1 to 6, the upper half 15 includes the top wall 11, the first sidewall extension 110, the second sidewall extension 111 and the channel 120. The lower half 16 includes the bottom wall 12, the first sidewall 13 and the second sidewall 14. In some embodiments, the opposing first and second sidewall extensions 110, 111 extend upwardly from opposing respective first and second edges 17, 18 of the top wall 11 of the housing 10. In other words, the first sidewall extension 110 extends upwardly from the first edge 17 of the top wall 11. The second sidewall extension 111 extends upwardly from the second edge 18 of the top wall 11. The first and second edges 17, 18 may be longitudinal edges of the top wall 11. In the illustrated embodiment, each of first and second edges 17, 18 is substantially straight. Alternatively, one or more of the first and second edges 17, 18 may be curved. In the illustrated embodiment, the first and second edges 17, 18 are substantially parallel to each other. In alternative embodiments, the first and second edges 17, 18 may be inclined to each other. An angle between the first and second edges 17, 18 may be less than about 3 degrees, less than about 5 degrees, or less than about 10 degrees. The first bottom surface 124 of the channel 120 is disposed between the first and second edges 17, 18 of the top wall 11.

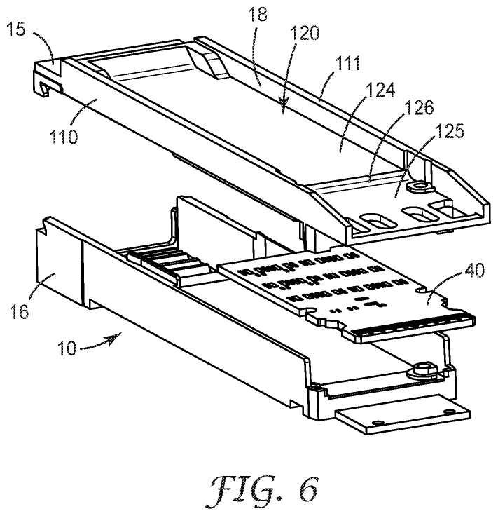

In the illustrated embodiment, as shown in FIGS. 5 and 6, the channel 120 has an open front end 121 and a closed back end 122. The open front end 121 is located near the first longitudinal end of the housing 10. The closed back end 122 is located near the second longitudinal end of the housing 10. Further, the closed back end 122 includes an inclined surface 123. An angle between the inclined surface 123 and the first bottom surface 124 is at least 20 degrees, at least 30 degrees, at least 45 degrees, or at least 60 degrees. The inclined surface 123 may be substantially planar. In some embodiments, the inclined surface 123 may include two or more inclined regions with different angles of inclination. The inclined surface 123 may alternatively be curved. The open front end 121 may allow air to enter the channel 120. The closed back end 122 may impede escape of air from the channel 120. This may facilitate transfer of heat generated by the electrical connector assembly 200.

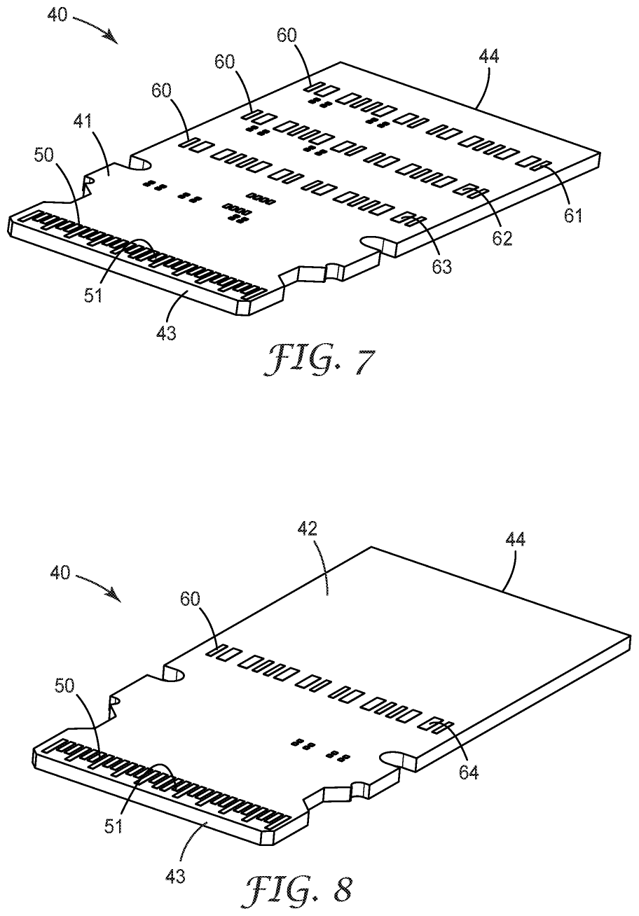

The circuit board 40 is at least partially disposed in the housing cavity 30 defined between the upper and lower halves 15, 16. Referring to FIGS. 7 and 8, the circuit board 40 includes an upper surface 41 and an opposing lower surface 42. In the illustrated embodiment, each of the upper surface 41 and the lower surface 42 is substantially planar. Alternatively, one or more of the upper and lower surfaces 41, 42 may be curved. The upper and lower surfaces 41, 42 may be substantially parallel to each other.

Alternatively, the upper and lower surfaces 41, 42 may be inclined to each other. An angle between the upper and lower surfaces 41, 42 may be less than about 3 degrees, less than about 5 degrees, or less than about 10 degrees.

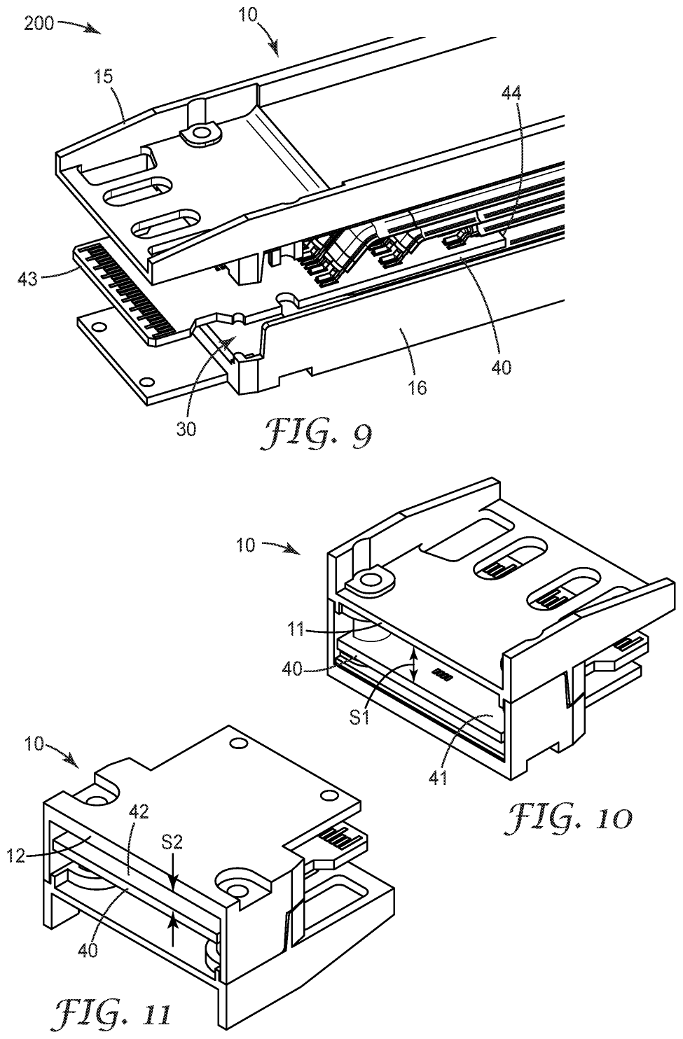

The circuit board 40 further includes a front end 43 and a cable end 44 opposite the front end 43 and disposed inside the housing cavity 30. Referring to FIGS. 7, 8 and 9, the front end 43 is disposed outside the housing cavity 30 near the first longitudinal end of the housing 10. However, the cable end 44 is disposed inside the housing cavity 30. The front end 43 and the cable end 44 may be longitudinal ends of the circuit board 40. The upper and lower surfaces 41, 42 are disposed between the front end 43 and the cable end 44. In the illustrated embodiment, the front end 43 and the cable end 44 are substantially parallel to each other. Alternatively, the front and cable ends 43, 44 may be inclined to each other. An angle between the front and cable ends 43, 44 may be less than about 3 degrees, less than about 5 degrees, or less than about 10 degrees.

The circuit board 40 may be a printed circuit board (PCB). The circuit board 40 may include one or more conductive tracks, conductive pads, and other conductive features disposed in a non-conductive substrate. The conductive features may be made of a metal or an alloy, such as copper. The conductive features may be arranged in one or more layers. The non-conductive substrate may be made of a polymeric resin. In the illustrated embodiment, the circuit board 40 includes a plurality of conductive front pads 50 (interchangeably referred to as “the front pads 50”) disposed on the upper and lower surfaces 41, 42 near the front end 43. The circuit board 40 further includes a plurality of conductive rear pads 60 (interchangeably referred to as “the rear pads 60”) disposed on the upper and lower surfaces 41, 42 between the front pads 50 and the cable end 44 and electrically connected to the front pads 50. The front pads 50 may be connected to respective rear pads 60 via conductive tracks. Each front pad 50 may have a suitable shape, such as rectangular, circular, elliptical, and so forth. Similarly, each rear pad 60 may have a suitable shape, such as rectangular, circular, elliptical, and so forth. Further, each front pad 50 may be made of an electrically conductive material, such as copper. Similarly, each rear pad 60 may be made of an electrically conductive material, such as copper. The front pads 50 may have a similar configuration or have different configurations. Similarly, the rear pads 60 may have a similar configuration or have different configurations.

In the illustrated embodiment, the plurality of conductive front pads 50 forms a first row of conductive front pads 51 disposed on the upper surface of the circuit board 40 near the front end 43. The plurality of conductive front pads 50 further forms a second row of conductive front pads 52 disposed on the lower surface 42 of the circuit board 40 near the front end 43. In some embodiments, a distance between the first row of conductive front pads 51 and the front end 43 of the circuit board 40 may be from about 0.3 mm to about 2 mm. Similarly, a distance between the second row of conductive front pads 52 and the front end 43 of the circuit board 40 may be from about 0.3 mm to about 2 mm.

The first row of conductive front pads 51 may be uniformly spaced or non-uniformly spaced on the upper surface 41. Similarly, the second row of conductive front pads 52 may be uniformly spaced or non-uniformly spaced on the lower surface 42. The first and second rows of conductive front pads 51, 52 may be disposed transversely on the circuit board 40. Further, the first and second rows of conductive front pads 51, 52 may be substantially identical to each other. The first and second rows of conductive front pads 51, 52 may also be aligned with each other.

In the illustrated embodiment, the plurality of conductive rear pads 60 forms a first row of conductive rear pads 61, a second row of conductive rear pads 62, and a third row of conductive rear pads 63 disposed on the upper surface 41 of the circuit board 40. Specifically, the plurality of conductive rear pads 60 forms the spaced apart substantially parallel first, second and third rows of conductive rear pads 61, 62, 63 disposed on the upper surface 41 of the circuit board 40 between the front pads 50 and the cable end 44. The plurality of conductive rear pads 60 further forms a fourth row of conductive rear pads 64 disposed on the lower surface 42 of the circuit board 40 between the front pads 50 and the cable end 44. Each of the first, second and third rows of conductive rear pads 61, 62, 63 may be disposed transversely on the upper surface 41 of the circuit board 40. The first, second and third rows of conductive rear pads 61, 62, 63 may be substantially identical to each other. Further, a spacing between the first, second and third rows of conductive rear pads 61, 62, 63 may be substantially equal. The first row of conductive rear pads 61 may be proximal to the cable end 44, while the third row of conductive rear pads 63 may be distal to the cable end 44. The fourth row of conductive rear pads 64 may be disposed transversely on the lower surface 42 of the circuit board 40. Further, the fourth row of conductive rear pads 64 may be substantially identical to and aligned with the third row of conductive rear pads 63. The first, second and third rows of conductive rear pads 61, 62, 63 may be electrically connected to the first row of conductive front pads 51. The fourth row of conductive rear pads 64 may be electrically connected to the second row of conductive front pads 52.

Referring to FIGS. 10 and 11, a separation between the rear pads 60 (shown in FIG. 7) disposed on the upper surface 41 of the circuit board 40 and the top wall 11 of the housing 10 is S1. Further, a separation between the rear pads 60 (shown in FIG. 8) disposed on the lower surface 42 of the circuit board 40 and the bottom wall 12 of the housing 10 is S2. S1 may be measured between the rear pads 60 disposed on the upper surface 41 and a bottom surface of the top wall 11. Further, S2 may be measured between the rear pads 60 disposed on the lower surface 42 and a top surface of the bottom wall 12. In some embodiments, S1 may be an average separation between the rear pads 60 disposed on the upper surface 41 and the top wall 11. Further, S2 may be an average separation between the rear pads 60 disposed on the lower surface 42 and the bottom wall 12. S1 is greater than S2. In some embodiments, S1 is greater than or equal to 1.5 times S2, i.e., S1≥1.5 S2. In some embodiments, S1 is greater than or equal to twice S2 (S1≥2 S2). In some embodiments, S1 is greater than or equal to 2.5 times S2 (S1≥2.5 S2). In some embodiments, S1 is greater than or equal to thrice S2 (S1≥3 S2). In some embodiments, S1 may be less than 5.4 mm, 4.8 mm or 4.2 mm. Further, S2 may be less than 1.8 mm, 1.6 mm or 1.4 mm. In some embodiments, S1 may be about 5.25 mm and S2 may be about 1.75 mm.

Since S1 is greater than S2, a space between the upper surface 41 and the top wall 11 is greater than a space between the lower surface 42 and the bottom wall 12. Therefore, a larger number of components may be accommodated in the space between the upper surface 41 and the top wall 11 as compared to the space between the lower surface 42 and the bottom wall 12. For example, the first, second and third flat cables 70, 80, 90 (shown in FIG. 3) may be stacked in the space between the upper surface 41 and the top wall 11. The fourth flat cable 100 (shown in FIG. 3) may be accommodated in the space between the lower surface 42 and the bottom wall 12.

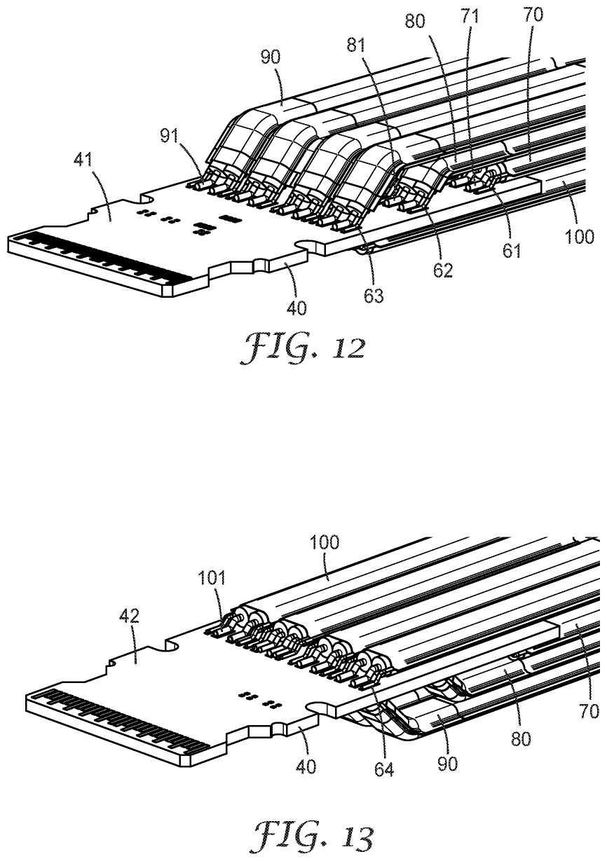

Referring to FIGS. 12 and 13, the stacked first, second and third flat cables 70, 80, 90 are terminated at the conductive rear pads 60 disposed on the top surface of the circuit board 40. Further, the fourth flat cable 100 is terminated at the conductive rear pads 60 disposed on the lower surface 42 of the circuit board 40. In the illustrated embodiment, the first, second and third flat cables 70, 80, 90 are terminated at the respective first, second and third rows of conductive rear pads 61, 62, 63. In other words, the first flat cable 70 is terminated at the first row of conductive rear pads 61. The second flat cable 80 is terminated at the second row of conductive rear pads 62. The third flat cable 90 is terminated at the third row of conductive rear pads 63. Moreover, the fourth flat cable 100 is terminated at the fourth row of conductive rear pads 64.

Each of the first, second, third and fourth flat cables 70, 80, 90, 100 includes a plurality of conductors 71, 81, 91, 101, respectively. At least some of the conductors 71, 81, 91, 101 may be surrounded by a dielectric material. Further, at least some of the conductors 71, 81, 91, 101 may be ground conductors which may not be surrounded by any dielectric material. The conductors 71, 81, 91, 101 which are surrounded by the dielectric material may be part of the insulated conductors of respective conductor sets. Each conductor set of each of the first, second, third and fourth flat cables 70, 80, 90, 100 may include a pair of the respective conductors 71, 81, 91, 101. Further, each of the first, second, third and fourth flat cables 70, 80, 90, 100 may include four such conductor sets. In some embodiments, one or more of the conductors 71, 81, 91, 101 may be stranded conductors.

A number of rear pads 60 in the first row may be equal to a number of conductors 71 of the first flat cable 70. A number of rear pads 60 in the second row may be equal to a number of conductors 81 of the second flat cable 80. Further, a number of rear pads 60 in the third row may be equal to a number of conductors 91 of the third flat cable 90. Moreover, a number of rear pads 60 in the fourth row may be equal to a number of conductors 101 of the fourth flat cable 100.

The conductors 71, 81, 91, 101 of the respective first, second, third and fourth flat cables 70, 80, 90, 100 may be coupled to the respective first, second, third and fourth rows of conductive rear pads 61, 62, 63, 64 by various methods. For example, an end of each of the first, second, third and fourth flat cables 70, 80, 90, 100 facing the circuit board 40 may be stripped to remove the shielding layers and the dielectric material, and then each of the conductors 71, 81, 91, 101 terminated at the respective first, second, third and fourth rows of conductive rear pads 61, 62, 63, 64. Examples of termination methods may include soldering, welding, crimping, mechanical clamping, and adhesive bonding.

In some embodiments, at least some of the conductors in the plurality of conductors 71, 81, 91, 101 have diameters not greater than 24 American Wire Gauge (AWG). In some embodiments, at least some of the conductors in the plurality of conductors 71, 81, 91, 101 have diameters not greater than 26 American Wire Gauge (AWG). In some embodiments, at least some of the conductors in the plurality of conductors 71, 81, 91, 101 have diameters not greater than 28 American Wire Gauge (AWG). In some embodiments, at least some of the conductors in the plurality of conductors 71, 81, 91, 101 have diameters not greater than 30 American Wire Gauge (AWG). Conductor diameters corresponding to 24 AWG, 26 AWG, 28 AWG and 30 AWG may be about 0.511 mm, about 0.405 mm, about 0.321 mm and about 0.255 mm, respectively.

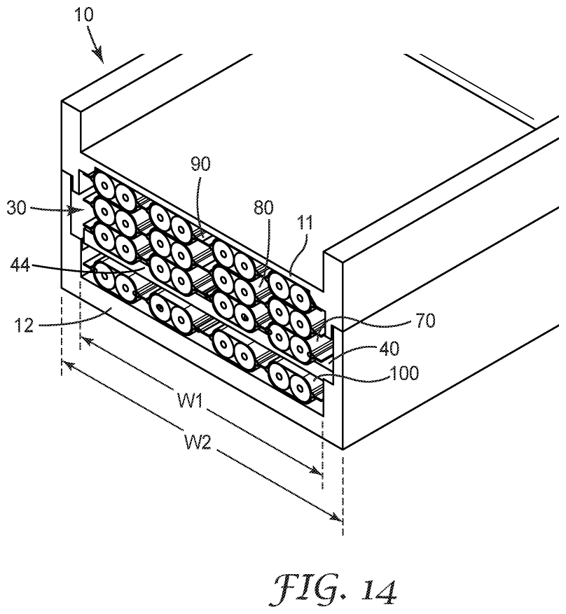

Referring to FIG. 14, in some embodiments, each of the first, second, third and fourth flat cables 70, 80, 90, 100 has a width W1 that is at least 0.6 times a width W2 of the housing 10 (W1≥0.6 W2).

Further, W1<W2 so that the first, second, third and fourth flat cables 70, 80, 90, 100 can be inserted within the housing 10. Therefore, W2>W1≥0.6 W2. The width W1 may be defined between longitudinal ends of the corresponding flat cable 70, 80, 90, 100. The width W1 of each flat cable 70, 80, 90, 100 may depend on the corresponding cable gauge. A larger cable gauge may lead to a greater value of the width W1. For example, a 24 AWG cable may have a greater value of the width W1 than that of a 26 AWG cable. In some embodiments, the width W1 may be less than 17 mm, 16 mm or 14 mm. The width W2 of the housing 10 may refer to a distance between outer surfaces of the first and second sidewalls 13, 14. The width W2 may be at least 28.3 mm, 27 mm or 23.3 mm. The width W2 and a height of the housing 10 may be chosen based on the gauge of each of the flat cables 70, 80, 90, 100. A width and a height of the housing cavity 30 may be chosen so that the flat cables 70, 80, 90, 100 may be accommodated within the housing cavity 30. Further, a width of the circuit board 40 may be less than 20 mm.

Referring to FIGS. 10, 11 and 14, the ratio between Si and S2 may be chosen such that the first, second and third flat cables 70, 80, 90 can be stacked between the upper surface 41 of the circuit board 40 and the top wall 11 of the housing 10. On the other hand, only the fourth flat cable 100 may be disposed between the lower surface 42 of the circuit board 40 and the bottom wall 12 of the housing 10. Increasing the value of S1 relative to S2 may allow larger cable gauges (e.g., 24 AWG) to be accommodated within the housing 10 while conforming to a form factor required by certain industry standards. For example, the electrical connector assembly 200 (shown in FIG. 1) may conform to the Octal Small Format Pluggable (OSFP) form factor defined by an industry standard created by a committee known as an MSA (Multi-Source Agreement). The electrical connector assembly 200 may have to conform to the form factor as required by the industry standard for connection with corresponding input or output ports. Larger gauge cables may allow higher speed of data transfer via the electrical connector assembly 200.

The industry standard may further require adequate transfer of heat generated by the electrical connector assembly 200. The channel 120 (shown in FIGS. 1, 5 and 6) may enable a suitable ratio between Si and S2 to accommodate larger cable gauges without reducing heat transfer from the electrical connector assembly 200. The channel 120 may allow sufficient air flow at the top of the housing 10 since the channel 120 extends uninterrupted between the first and second sidewall extensions 110, 111. Specifically, absence of any interrupting features (e.g., fins) in the channel 120 may allow an adequate volume of air flow through the channel 120 while allowing a greater value of Si for accommodating larger cable gauges. Therefore, a lower height of the channel 120 may be chosen to allow a greater value of S1 while ensuring sufficient air flow through the channel 120. Further, an overall height of the housing 10 may remain within the form factor required by the industry standard. The electrical connector assembly 200 may therefore accommodate multiple flat cables of larger cable gauge (e.g., 24 AWG) within the form factor required by the industry standard without reducing the air flow required for adequate heat transfer.

Unless otherwise indicated, all numbers expressing feature sizes, amounts, and physical properties used in the specification and claims are to be understood as being modified by the term “about”. Accordingly, unless indicated to the contrary, the numerical parameters set forth in the foregoing specification and attached claims are approximations that can vary depending upon the desired properties sought to be obtained by those skilled in the art utilizing the teachings disclosed herein.

Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof

1. An electrical connector assembly, comprising:
a housing comprising opposing top and bottom walls and opposing first and second sidewalls connecting the top and bottom walls, the top and the bottom walls and the opposing first and second sidewalls defining a housing cavity therebetween;
a circuit board at least partially disposed in the housing cavity and comprising:
an upper surface and an opposing lower surface;
a front end and a cable end opposite the front end and disposed inside the housing cavity;
a plurality of conductive front pads disposed on the upper and lower surfaces near the front end; and
a plurality of conductive rear pads disposed on the upper and lower surfaces between the front pads and the cable end and electrically connected to the front pads, a separation between the rear pads disposed on the upper surface and the top wall of the housing being S1, a separation between the rear pads disposed on the lower surface and the bottom wall of the housing being S2, S1≥1.5 S2;
stacked first, second and third flat cables terminated at the conductive rear pads disposed on the top surface of the circuit board;
a fourth flat cable terminated at the conductive rear pads disposed on the lower surface of the circuit board; and
opposing first and second sidewall extensions extending upwardly from the opposing respective first and second sidewalls of the housing and defining an open top channel therebetween that extends uninterrupted between the opposing first and second sidewall extensions.

2. The electrical connector assembly of claim 1, wherein the housing comprises an upper half removably assembled to a lower half, the upper and lower halves defining the housing cavity therebetween.

3. The electrical connector assembly of claim 1, wherein the opposing first and second sidewall extensions extend upwardly from opposing respective first and second edges of the top wall of the housing.

4. The electrical connector assembly of claim 1, wherein the plurality of conductive front pads forms a first row of conductive front pads disposed on the upper surface of the circuit board near the front end, and a second row of conductive front pads disposed on the lower surface of the circuit board near the front end.

5. The electrical connector assembly of claim 1, wherein the plurality of conductive rear pads forms spaced apart substantially parallel first, second and third rows of conductive rear pads disposed on the upper surface of the circuit board between the front pads and the cable end, and a fourth row of conductive rear pads disposed on the lower surface of the circuit board between the front pads and the cable end.

6. The electrical connector assembly of claim 1, wherein S1≥2 S2.

7. The electrical connector assembly of claim 1, wherein the channel has an open front end and a closed back end, the closed back end comprising an inclined surface.

8. The electrical connector assembly of claim 1, wherein the channel comprises a substantially flat first bottom surface and a substantially flat second bottom surface, the first and second bottom surfaces connected via one or more steps.

9. The electrical connector assembly of claim 1, wherein the channel is configured to transfer heat generated by the electrical connector assembly.

10. The electrical connector assembly of claim 1, wherein each of the first, second, third and fourth flat cables comprises a plurality of conductors, and wherein at least some of the conductors in the plurality of conductors have diameters not greater than 24 American Wire Gauge (AWG).

11. The electrical connector assembly of claim 5, wherein the first, second and third flat cables are terminated at the respective first, second and third rows of conductive rear pads, and the fourth flat cable is terminated at the fourth row of conductive rear pads.

12. The electrical connector assembly of claim 1, wherein S1≥2.5 S2.

13. The electrical connector assembly of claim 1, wherein each of the first, second, third and fourth flat cables has a width that is at least 0.6 times a width of the housing.

14. The electrical connector assembly of claim 10, wherein at least some of the conductors in the plurality of conductors have diameters not greater than 26 American Wire Gauge (AWG).

15. The electrical connector assembly of claim 10, wherein at least some of the conductors in the plurality of conductors have diameters not greater than 28 American Wire Gauge (AWG).

16. The electrical connector assembly of claim 10, wherein at least some of the conductors in the plurality of conductors have diameters not greater than 30 American Wire Gauge (AWG).
